(19) United States
(12) Patent Application Publication
(10) Pub. No.: US 2005/0286624 A1
(43) Pub. Date: Dec. 29, 2005

(54) Method and apparatus to automatically control a step size of an LMS type equalizer

(76) Inventor: Sung-woo Park, Suwon-si (KR)

Correspondence Address: STANZIONE & KIM, LLP, 919 18TH STREET, N.W., SUITE 440, WASHINGTON, DC, 20006, US

(21) Appl. No.: 11/109,849

(22) Filed: Apr. 20, 2005

(30) Foreign Application Priority Data
Jun. 28, 2004 (KR) 2004-48939

(51) Int. Cl. H03H 7/40

(52) U.S. Cl. 375/232

(57) ABSTRACT

A method and apparatus to automatically control a step size of a least mean squares (LMS) equalizer. An optimal step size can be selected by checking a signal to noise ration (SNR) of the LMS equalizer output according to a change in the step size. The LMS equalizer includes a step size decision block, which makes a relatively large change to the step size within predetermined upper and lower limits, and checks the SNR of the LMS equalizer output according to the change made to the step size. If the SNR becomes greater than a certain value, the step size is again adjusted with a higher precision to select an optimal step size in a given channel environment. Further, the LMS equalizer is capable of selecting an optimal tap coefficient within a shorter period of time, and a hardware system used to implement the apparatus to automatically control the step size is simple, yet optimized in a given channel environment.

### CROSS-REFERENCE TO RELATED APPLICATIONS

This application claims the benefit under 35 U.S.C. § 119 of Korean Patent Application No. 2004-48939, filed on Jun. 28, 2004 in the Korean Intellectual Property Office, the entire content of which is incorporated herein by reference.

### BACKGROUND OF THE INVENTION

1. Field of the Invention

The present general inventive concept relates to a method and an apparatus to automatically control a step size of an LMS (Least Mean Square) equalizer, thereby optimizing performance of the LMS equalizer under varying channel environments by adjusting the step size of the LMS equalizer according to an SNR (Signal to Noise Ratio) of an output of the LMS equalizer.

2. Description of the Related Art

A digital communication channel (e.g., in a digital broadcast) may sometimes manifest abnormal characteristics due to limited bandwidth environments. As a result, unexpected intersymbol interference (ISI) occurs in an amplitude and a phase of the digital communication channel. The intersymbol interference is a major obstacle to a more effective use of frequency band and performance improvement. Therefore, it is necessary to use an equalizer to compensate a signal that is distorted by the intersymbol interference.

The most important factor for improving performance of the equalizer is adapting a tap coefficient to varying channel environments. Adapting the tap coefficient of the equalizer is performed according to a step size.

FIG. 1 is a block diagram illustrating a conventional LMS equalizer 100. The LMS equalizer is widely used because of its simple and easy implementation. As illustrated in FIG. 1, the conventional LMS equalizer 100 comprises an equalizer filter 101, a symbol decision unit 103, and a coefficient update unit 105.

An input signal is passed through the equalizer filter 101, and the equalizer filter 101 produces an output signal yₖ. The symbol decision unit 103 obtains an error eₖ by subtracting the output signal yₖ and a reference signal dₖ (e.g. a reference symbol signal in a digital broadcast receiver), which includes the most approximate symbols to the output signal yₖ of the equalizer filter 101. The coefficient update unit 105 receives the error eₖ and updates a tap coefficient based on a tap coefficient update algorithm employing a step size (Δ). Equation 1 below represents the coefficient update algorithm.
Cₖ₊₁=Cₖ+ΔeₖXₖ [Equation 1]
where ‘k’ is an iteration count or a time interval between symbols, Cₖ is a k-th iteration coefficient vector, Xₖ is a tap vector, Δ is the step size, and eₖ is the error. The tap vector Xₖ includes the input signal (data) provided to the equalizer filter 101 and distributed among a plurality of taps T. The number of elements of a vector (i.e., the tap vector Xₖ or the coefficient vector Cₖ) is equal to the number of the plurality of taps T of the equalizer 100.

Usually, the step size is a single fixed value, or is selected out of several values. When a user needs to select the step size, the user may initially set the step size or may select the step size with reference to channel information. Step sizes that depend on how large error values are have a great impact upon a convergence speed and a residual error. For example, if a large value is used as the step size, the convergence speed might increase , but the residual error after convergence would be large. In contrast, if a small value is used as the step size, the convergence speed might decrease, but the residual error after convergence would be small.

With more accurate channel information and an optimal step size value for the channel, the performance of the equalizer can be maximized. However, it is very difficult to obtain accurate channel information and an optimal step size. Accordingly, a complex hardware system is necessary to obtain the more accurate channel information. Furthermore, when only one step size value is available for the operation of the equalizer, the user cannot always expect the best performance of the equalizer under different channel environments. Therefore, there is a need to develop a method of automatically controlling a step size of the equalizer in accordance with different channels without requiring a complex hardware system.

### SUMMARY OF THE INVENTION

The present general inventive concept provides a method and apparatus to automatically control a step size of a least mean squares (LMS) equalizer.

Additional aspects and advantages of the present general inventive concept will be set forth in part in the description which follows and, in part, will be obvious from the description, or may be learned by practice of the general inventive concept.

The foregoing and/or other aspects and advantages of the present general inventive concept are achieved by providing an apparatus to automatically control a step size of a least mean squares (LMS) equalizer having an adaptive step size, the apparatus comprising an SNR (Signal to Noise Ratio) measurement block to measure an SNR of an output signal from the LMS equalizer, and a step size decision block to receive the SNR from the SNR measurement block, to change the step size used to update a tap coefficient of the LMS equalizer until the SNR exceeds a predetermined value, and to transfer the step size to the LMS equalizer.

The SNR measurement block may output a cumulative error value from the LMS equalizer to represent the SNR, in which the cumulative error value is a sum of error values accumulated, and an error value is a difference between an output of an equalizer filter of the LMS equalizer and a reference symbol signal, and the cumulative error value is inversely proportional to the SNR.

While the LMS equalizer operates at a current step size and the error value converges, the SNR measurement block may add the error value and output the error value per operating time of the LMS equalizer.

The equalizer may add the error values according to a period of at least one field signal of a digital broadcast data received through 8 VSB form, and the SNR measurement block outputs the cumulative error value per period.

The cumulative error value may comprise a sum of error values generated when at least one of a test stream data and a segment sync symbol of a field segment is input to the LMS equalizer.

The step size decision block may comprise a first step size decision unit to select a first step size between a predetermined upper limit and a predetermined lower limit and to change the first step size at predetermined regular time intervals to ensure that the first step size is increased or decreased sequentially by a predetermined first size, and to output the changed first step size, a second step size decision unit to select a second step size within a range defined by the predetermined first size and to change the second step size at the predetermined regular time intervals to ensure that the second step size is increased or decreased sequentially by a predetermined second size, and to output the changed second step size, and an adder to add an output of the first step size decision unit and an output of the second step size decision unit, and to transfer a sum thereof to the LMS equalizer as a final step size.

The predetermined regular time intervals may comprise time taken by the LMS equalizer to converge periodically according to the final step size.

The predetermined regular time intervals may comprise at least one field signal period of a digital broadcast data received through 8 VSB form periodically.

The first step size decision unit can receive the cumulative error value output from the SNR measurement block, and if the cumulative error value is less than a predetermined first threshold, the first step size is maintained without change, and the second step size decision unit can receive the cumulative error value output from the SNR measurement block, and if the cumulative error value is less than a predetermined second threshold that is less than the predetermined first threshold, or if the cumulative error value is greater than the predetermined first threshold, the second step size is maintained without change.

The foregoing and/or other aspects and advantages of the present general inventive concept are also achieved by providing a receiver comprising a step size auto-controlling device of an LMS equalizer to adjust a step size of the LMS equalizer, thereby compensating distortions of a received signal under different channel environments.

The foregoing and/or other aspects and advantages of the present general inventive concept are also achieved by providing a digital broadcast receiver comprising a step size auto-controlling device of an LMS equalizer to adjust a step size of the LMS equalizer, thereby compensating distortions of a digital broadcast signal in 8 VSB (Vestigial Side Band) form under different channel environments.

The foregoing and/or other aspects and advantages of the present general inventive concept are also achieved by providing a method of automatically controlling a step size of an LMS equalizer, the method comprising measuring a signal to noise ratio (SNR) of an output signal of the LMS equalizer, and changing the step size until the SNR measurement exceeds a predetermined value, and transferring the changed step size to the LMS equalizer.

The measuring of the SNR may comprise measuring a cumulative error value received from the LMS equalizer, the cumulative error value being a sum of error values accumulated, in which an error value is a difference between an output of an equalizer filter of the LMS equalizer and a reference symbol signal, and the cumulative error value is inversely proportional to the SNR.

The measuring of the SNR may further comprise measuring the error value of the LMS equalizer while the LMS equalizer operates at a current step size and converges, and the cumulative error value is determined by adding the error values accumulated while the LMS equalizer operates at the current step size.

The measuring of the SNR may further comprise adding the error values of at least one field signal period of a digital broadcast data received through 8 VSB form, and the SNR measurement block outputs the cumulative error value per field signal period.

The cumulative error value may comprise a sum of errors generated when at least one of a test stream data and a segment sync symbol of a field segment is input to the LMS equalizer.

The method may further comprise selecting a first step size between a predetermined upper limit and a predetermined lower limit while changing the first step size at predetermined regular time intervals to ensure that the first step size is increased or decreased sequentially by a first predetermined size, selecting a second step size within a range defined by the first predetermined size while changing the second step size at the predetermined regular time intervals to ensure that the second step size is increased or decreased sequentially by a second predetermined size, and adding the first step size and the second step size to determine a final step size to be transferred to the LMS equalizer.

The time taken by the LMS equalizer to converge periodically according to the determined final step size may be equal to the predetermined regular time intervals.

The predetermined regular time intervals may comprise at least one field signal period of a digital broadcast data received through 8 VSB form periodically.

The selecting of the first step size may comprise receiving the measured cumulative error value, and if the cumulative error value is less than a predetermined first threshold, the first step size is maintained without change. The selecting of the second step size may comprise receiving the measured cumulative error value, and if the cumulative error value is less than a predetermined second threshold that is less than the predetermined first threshold, or if the cumulative error value is greater than the predetermined first threshold, the second step size is maintained without change.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a block diagram illustrating a conventional LMS (least mean square) equalizer;

FIG. 2 illustrates an LMS equalizer including a step size auto-controlling device according to an embodiment of the present general inventive concept;

FIG. 3 is a block diagram illustrating the step size auto-controlling device of the LMS equalizer of FIG. 2;

FIG. 4A and FIG. 4B are diagrams illustrating operation of a step size decision block 330 of the step size auto-controlling device of FIG. 3; and

FIG. 5 is a flow chart illustrating operation of the step size auto-controlling device of FIG. 3.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures.

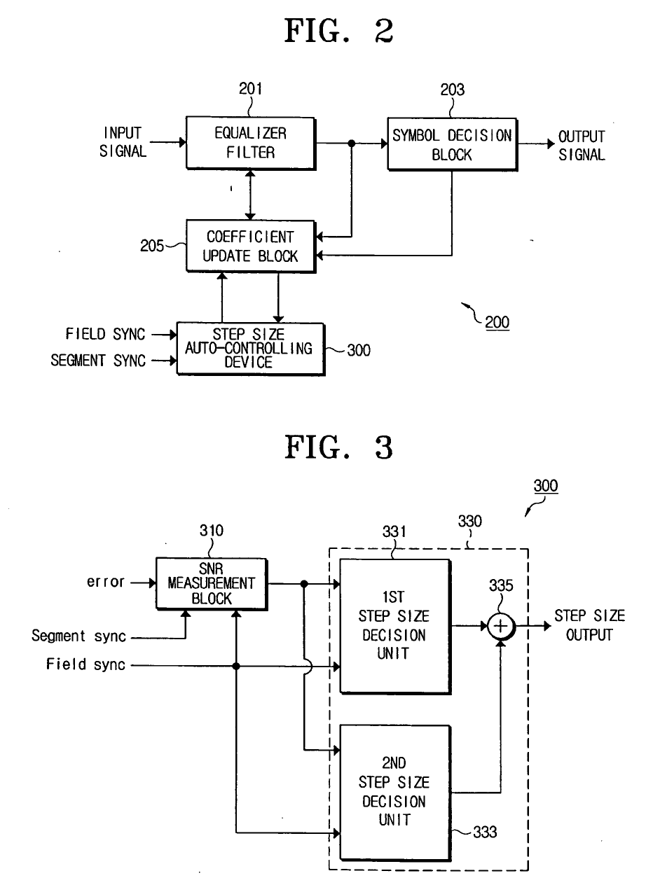

FIG. 2 illustrates an LMS (least mean square) equalizer 200 including a step size auto-controlling device according to an embodiment of the present general inventive concept. The LMS equalizer 200 in FIG.21 may comprise an LMS adaptive linear equalizer to compensate for distortion among different received channels that results from varying channel environments. The LMS equalizer 200 illustrated in FIG. 2 of the present general inventive concept can be applied to a digital radio broadcast receiver, for example, to compensate for distortion in digital radio broadcast signals. Although the following description of the LMS equalizer 200 assumes that the LMS equalizer 200 is applied to the digital radio broadcast receiver environment, it should be understood that the LMS equalizer 200 of the present general inventive concept can be used with other applications.

Structure of radio broadcast data received over digital broadcast channels will now be described. In general, a data frame used in transmission of a digital broadcast signal according to the 8 VSB (Vestigial Side Band) transmission form is composed of two data fields. Each data field includes 313 data segments. The first data segment among the 313 data segments in a data field is a field sync signal, which comprises an equalizer test data stream (hereinafter, it is referred to as a ‘test stream signal’) to be used by the LMS equalizer 200 of a receiver. Each data segment comprises a plurality of symbols. The first four symbols of each data segment comprise a segment sync signal. According to the TDS-OFDM (time domain synchronous-OFDM) form, which is an OFDM (orthogonal frequency division multiplexing) form (i.e., another kind of digital broadcast transmission form), an OFDM frame signal generated by an insertion of the test stream signal is transmitted.

Referring to FIG. 2, a step size auto-controlling device 300 of the LMS equalizer 200 according to an embodiment of the present general inventive concept is connected to a coefficient update block 205. Additionally, the step size auto-controlling device 300 is connected to an equalizer filter 201 and a symbol decision block 203 via the coefficient update block 205.

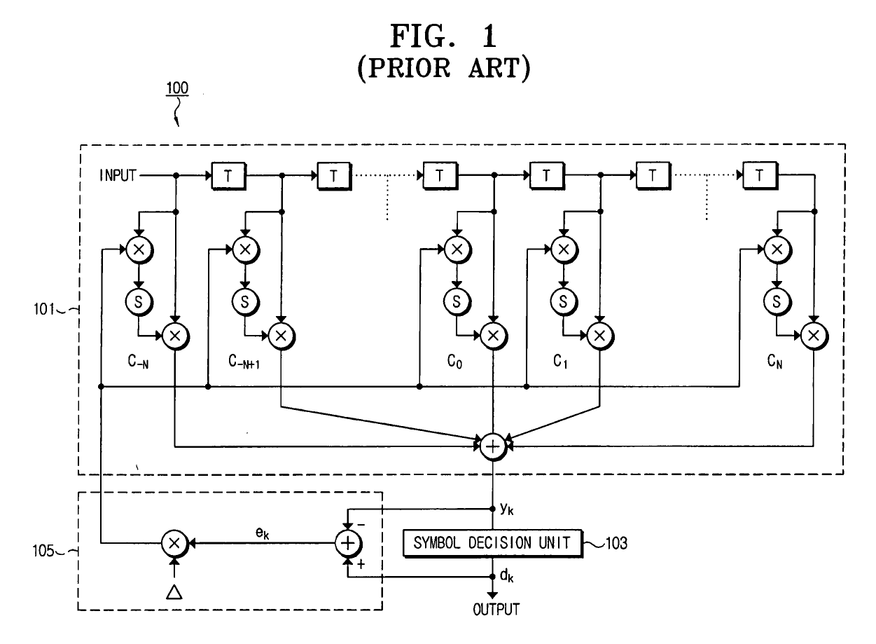

The equalizer filter 201 may comprise an LMS type linear equalizer filter similar to the equalizer filter 101 illustrated in FIG. 1.

The symbol decision block 203 may comprise a slicer or viterbi decoder, and decides a reference symbol signal from outputs of the equalizer filter 201.

The coefficient update block 205 updates a tap coefficient of the equalizer filter 201 by applying [Equation 1] described above. The tap coefficient may comprise a tap coefficient vector that includes a plurality of tap coefficients for the equalizer filter 201. Regarding the application of [Equation 1], an error value is obtained by subtracting an output of the equalizer filter 201 from an output of the symbol decision block 203. The step size is transferred from the step size auto-controlling device 300 to the coefficient update block 205.

The step size auto-controlling device 300 receives the error value from the coefficient update block 205 along with the field sync and the segment sync of a received signal. The step size auto-controlling device 300 automatically selects an adaptive step size according to a given channel environment of the received signal, and transfers the selected adaptive step size to the coefficient update block 205.

FIG. 3 is a block diagram illustrating the step size auto-controlling device 300 of the LMS equalizer 200 of FIG. 2. As illustrated in FIG. 3, the step size auto-controlling device 300 comprises an SNR measurement block 310 and a step size decision block 330.

The SNR measurement block 310 measures an SNR (Signal to Noise Ratio) of the output signal of the LMS equalizer 200, and transfers the SNR to the step size decision block 330. The SNR measurement block 310 receives the error value from the coefficient update block 205 and calculates the SNR accordingly. A sum of error values from the coefficient update block 205 for a predetermined amount of time is inversely proportional to the SNR. Thus, the sum, i.e., the sum of the error values for the predetermined amount of time (hereinafter, referred to as a cumulative error value) can be represented by the SNR measurement. The predetermined amount of time during which the SNR measurement block 310 adds the error values in order to measure the cumulative error value equals the time taken by the LMS equalizer 200 to operate according to one step size and converge. The LMS equalizer 200 converges when a minimum mean square error (MSE) is reached by repeatedly determining an error value and updating the tap coefficient according to the determined error value and the one step size. The predetermined amount of time during which the cumulative error value is measured is set to the amount of time it takes the LMS equalizer 200 to converge with the one step size so that a response of the LMS equalizer 200 to a corresponding step size (i.e., the signal to noise ratio for the predetermined amount of time) can more easily be evaluated. The predetermine amount of time can be a period of one or two fields of data (e.g., ‘1 field’ may be used).

Referring to FIGS. 2 and 3, the SNR measurement block 310 measures the SNR of an output signal of data only if the LMS equalizer 200 already knows the data (i.e., if the symbol decision block 203 has determined the reference symbol signal), since the SNR measurement block 310 measures the signal to noise ratio according to the reference symbol signal and the output of the equalizer filter 201. For example, suppose that radio digital broadcast data is received according to the 8 VSB transmission form. The SNR measurement block 310 can only measure the test stream signal contained in the field sync and the four symbols of the segment sync.

The step size decision block 330 selects an adaptive step size according to a given channel environment, and outputs the step size to the coefficient update block 205. At first, the step size decision block 330 makes a large change to the step size within a predetermined upper limit and lower limit, and the SNR measurement block 310 determines the SNR of the LMS equalizer 200. If the step size becomes greater than a certain value, the step size decision block 330 makes a smaller change to the step size until an optimal step size is selected according to a given channel environment. However, since the SNR measurement block 310 uses the cumulative error value to measure the SNR, the cumulative error value and the SNR will be used interchangeably in the following description.

Referring to FIGS. 2 and 3, the step size decision block 330 comprises a first step size decision unit 331, a second step size decision unit 333, and an adder 335. The adder 335 adds a first step size selected by the first step size decision unit 331 to a second step size selected by the second step size decision unit 333. A resulting final step size produced by the adder 335 is output to the coefficient update block 205. The final step size output by the step size decision block 330 is maintained (without being changed) until the LMS equalizer 200 converges. Once the LMS equalizer 200 converges, a new final step size is selected according to the SNR (i.e., the cumulative error value measured during the time it takes the LMS equalizer 200 to converge according to the final step size) of the output of the converged LMS equalizer 200.

The step size decision block 330 makes a decision with reference to a first and a second threshold. Accordingly, a decision result and operations of the first and the second step size decision units 331 and 333 are controlled.

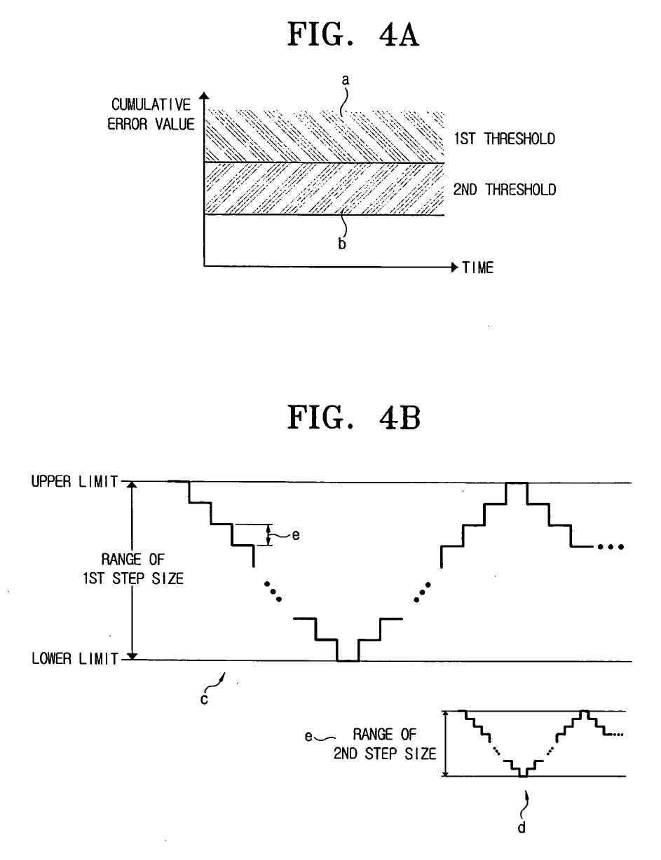

FIG. 4A and FIG. 4B are diagrams illustrating the operation of the step size decision block 330 of FIG. 3. Referring to FIGS. 2, 3, and 4A, when the cumulative error value falls within a region (a), the first step size decision unit 331 operates while changing the first step size, and the second step size decision unit 333 maintains the second step size at a current value. On the other hand, when the cumulative error value falls within a region (b) the second step size decision unit 333 operates while changing the second step size, and the first step size decision unit 331 maintains the first step size at a current value. If the cumulative error value is less than a second threshold located at a lower boundary of the region (b), the first step size decision unit 331 and the second step size decision unit 333 maintain the first step size and the second step size at their current values, respectively.

If the cumulative error value is greater than a first threshold located at a boundary between the region (a) and the region (b) (or if the SNR is very low), the step size decision block 330 controls the first step size decision unit 331 to cause a relatively large change to the first step size, thereby affecting a large change in the final step size for operation of the LMS equalizer 200. When the cumulative error value is decreased to be less than the first threshold (or when the SNR reaches a certain level), the step size decision block 330 determines that the LMS equalizer 200 has adapted to some degree according to a given channel environment. Accordingly, the second step size decision unit 333 starts adjusting the second step size, thereby affecting a smaller change in the final step size in order to adjust the final step size more precisely.

Referring to FIGS. 2, 3, and 4B, the first step size decision unit 331 changes the first step size according to a predetermined first size (e) out of a plurality of steps within a range (c) defined by an upper limit and a lower limit. The second step size decision unit 333 changes the second step size with a higher precision according to a predetermined second size within a range (d) defined by the predetermined first size (e). Thus, the first step size can provide a larger change in the final step size in increments of the predetermined first size (e) within the range (c), and the second step size can provide smaller and more precise changes in the final step size in increments of the predetermined second size within the range (d).

For instance, the first step size decision unit 331 selects a first step size between the predetermined upper and lower limits that define the range (c). The first step size decision unit 331 changes first step sizes at predetermined regular intervals to ensure that the first step sizes are gradually increased or decreased by the predetermined first size (e), and outputs the changed first step sizes.

The first step size decision unit 331 selects a first step size, and outputs the selected first step size. This first step size output from the first step size decision unit 331 is maintained for a predetermined amount of time. This predetermined amount of time corresponds to the time taken by the LMS equalizer 200 to converge according to the final step size, and an error value is added during the predetermined amount of time to calculate the cumulative error value. That is, a period of one or two field (sync) signals can be used to determine when the predetermined amount of time has elapsed (e.g., ‘1 field’ may be used in the present embodiment).

The first step size decision unit 331 outputs the selected first step size, and compares the cumulative error value input from the SNR measurement block 310 with the first threshold. If the cumulative error value is less than the first threshold, the first step size currently being output by the step size decision unit 331 is maintained.

The second step size decision unit 333 selects the second step size according to the predetermined second size within the predetermined first size (e) (and the range (d)), as illustrated in FIG. 4B. Thus, the second step size in this case is increased or decreased sequentially by less than the predetermined first size (e) each time. When the second step size decision unit 333 selects a second step size and outputs the selected second step size, the second step size output from the second step size decision unit 333 is maintained for the predetermined time required for the LMS equalizer 200 to converge according to the final step size, as described above with reference to the first step size decision unit 331. While outputting the second step size, the second step size decision unit 333 compares the cumulative error value input from the SNR measurement block 310 with the first and the second thresholds. If the cumulative error value is either less than the second threshold or greater than the first threshold, the second step size is maintained without being changed.

The adder 335 adds the outputs of the first step size decision unit 331 and the second step size decision unit 333, and transfers the sum thereof as the final step size to the LMS equalizer 200.

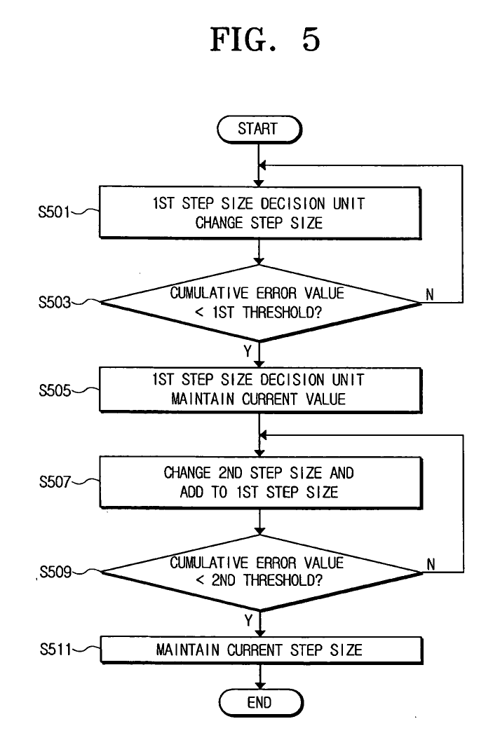

FIG. 5 is a flow chart illustrating the operation of the step size auto-controlling device 300 of FIG. 3. The operation of the step size auto-controlling device 300 in the LMS equalizer 200 will be described with reference to FIGS. 3, 4A, 4B, and 5.

When the LMS equalizer 200 is in operation, the adder 335 in the step size decision block 330 adds the first step size selected by the first step size decision unit 331 and the second step size selected by the second step size decision unit 333 to determine the final step size. The final step size is then transferred to the coefficient update block 205 at an operation S501.

The SNR measurement block 310 measures a cumulative error value of the output of the LMS equalizer 200 according to the final step size determined at the operation S501. The first step size decision unit 331 receives from the SNR measurement block 310 the cumulative error value after one field of time, and decides whether the cumulative error value is less than the first threshold at an operation S503.

If the cumulative error value is determined to be less than the first threshold at the operation S503, the first step size decision unit 331 maintains the first step size at its current value at an operation S505. The second step size decision unit 333 changes the second step size to a new second step size within the range (d) illustrated in FIG. 4B, and outputs the new second step size. The adder 335 adds the first step size to the second step size, and outputs the sum as the final step size to the coefficient update block 205 at an operation S507.

On the other hand, if it is determined that the cumulative error value is greater than the first threshold at the operation S503, the operation 501 is repeated. That is, a new first step size is selected within the range (c) defined by the upper and lower limits (FIG. 4B).

The second step size decision unit 333 receives the cumulative error value after one field of time from the SNR measurement block 310, and decides whether the cumulative error value is less than the second threshold at an operation S509.

If it is determined that the cumulative error value is less than the second threshold, the second step size is maintained at its current value, and the adder 335 also maintains the final step size at its current value at operation S511.

However, if it is determined that the cumulative error value is greater than the second threshold at the operation S509, the operation S507 is repeated. That is, a new second step size is selected within the range of the predetermined first size (e) according to the predetermined second size.

In this manner, it becomes possible to select an optimal step size according to a given channel environment. Although FIG. 5 illustrates that the first step size is processed first at the operations S501, S503, and S505, and the second step size is processed second at the operations S507, S509, and S511, it should be understood that the first step size and the second step size can be processed together and/or simultaneously. For example, once either the first or the second step sizes are changed, the cumulative error value can be measured and compared to the first and second threshold by the same operation. At a subsequent operation, the first step size, the second step size, or neither step size can be changed according to the comparison.

The present general inventive concept makes it possible to select an optimal step size according to a given channel environment without utilizing a separate complicated channel analyzer by simply selecting an approximate step size according to an SNR of an equalizer output. Further, by employing a 2-step tracing operation to adjust the step size, it becomes possible to select the optimal step size within a short period of time. Therefore, any equalizer employing the method and apparatus to automatically control a step size of the LMS equalizer according to an embodiment of the present general inventive concept is able to obtain an optimal tap coefficient within a short period of time. The hardware system used to implement the present general inventive concept is simple, yet an optimum equalizer in a given channel environment can be realized.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents

1. An apparatus to automatically control a step size of a least mean square (LMS) equalizer having an adaptive step size, the apparatus comprising:
an SNR (Signal to Noise Ratio) measurement block to measure an SNR of an output signal from the LMS equalizer; and
a step size decision block to receive the SNR from the SNR measurement block, to change a step size used to update a tap coefficient of the LMS equalizer until the SNR exceeds a predetermined value, and to transfer the changed step size to the equalizer.

2. The apparatus according to claim 1, wherein the SNR measurement block outputs a cumulative error value from the LMS equalizer to represent the SNR, the cumulative error value being a sum of error values accumulated, in which an error value is a difference between an output of an equalizer filter of the LMS equalizer and a reference symbol signal, and the cumulative error value is inversely proportional to the SNR.

3. The apparatus according to claim 2, wherein, while the LMS equalizer operates at a current step size and the error value converges, the SNR measurement block adds the error value and outputs the error value per unit operating time.

4. The apparatus according to claim 2, wherein the LMS equalizer adds the error values according to a period of at least one field signal of a digital broadcast data received through 8 VSB form, and the SNR measurement block outputs the cumulative error value per period.

5. The apparatus according to claim 4, wherein the cumulative error value is a sum of error values generated when at least one of a test stream data and a segment sync symbol of a field segment is input to the LMS equalizer.

6. The apparatus according to claim 1, wherein the step size decision block comprises:
a first step size decision unit to select a first step size between a predetermined upper limit and a predetermined lower limit and to change the first step size at predetermined regular time intervals such that the first step size is increased or decreased sequentially by a predetermined first size, and to output the changed first step size;
a second step size decision unit to select a second step size within a range defined by the predetermined first size and to change the second step size at the predetermined regular time intervals such that the second step size is increased or decreased sequentially by the predetermined second size, and to output the changed second step size; and
an adder to add an output of the first step size decision unit and an output of the second step size decision unit and to transfer a sum thereof to the LMS equalizer as a final step size.

7. The apparatus according to claim 6, wherein the predetermined regular time intervals comprise time taken by the LMS equalizer to converge periodically according to the final step size.

8. The apparatus according to claim 6, wherein the predetermined regular time intervals comprise at least one field signal period of a digital broadcast data received through 8 VSB form periodically.

9. The apparatus according to claim 6, wherein:
the first step size decision unit receives a cumulative error value output from the SNR measurement block, and if the cumulative error value is less than a first predetermined threshold, the first step size is maintained without change; and
the second step size decision unit receives the cumulative error value output from the SNR measurement block, and if the cumulative error value is less than a second predetermined threshold that is less than the first predetermined threshold, or if the cumulative error value is greater than the first predetermined threshold, the second step size is maintained without change.

10. A least mean square (LMS) equalizer having an adaptive step size, comprising:
a filter unit having a tap coefficient;
an error measurement unit to determine an error value of an output of the filter unit and to update the tap coefficient according to a step size; and
a step size decision unit to receive the determined error value from the error measurement unit and to maintain the step size or change the step size by one of a first amount and a second amount according to the determined error value.

11. The equalizer of claim 10, wherein the step size decision unit determines whether the error value falls within a predetermined error range, changes the step size by the first amount when the error value is larger than the predetermined error range, changes the step size by the second amount when the error value falls within the predetermined error range, and maintains the step size when the error value is less than the predetermined error range.

12. The equalizer of claim 10, wherein the first amount is a multiple of the second amount.

13. The equalizer of claim 10, wherein the error value comprises a cumulative error value taken over a predetermined time that the filter unit operates.

14. The equalizer of claim 13, wherein the step size decision unit comprises:
a first step size decision unit to output a first step size, to determine whether the cumulative error value exceeds a first threshold, and to change the first step size by the first amount when the cumulative error value exceeds the first threshold; and
a second step size decision unit to output a second step size, to determine whether the cumulative error value exceeds a second threshold that is less than the first threshold, and to change the second step size by the second amount when the cumulative error value falls between the first threshold and the second threshold; and
an adder to add the first step size and the second step size to determine a final step size and to provide the final step size to the error measurement unit as the step size.

15. The equalizer of claim 14, wherein the final step size is maintained until the error value of the LMS equalizer converges.

16. The equalizer of claim 13, wherein the predetermined time is periodic and comprises an amount of time it takes the LMS equalizer to converge on a minimum mean squared error according to the step size.

17. The equalizer of claim 13, wherein the predetermined time is periodic and depends on one of a field sync signal and a segment sync signal.

18. The equalizer of claim 10, further comprising:
a symbol decision unit to receive an output of the filter unit, to decide a reference symbol signal, and to provide the reference symbol signal to the error measurement unit

19. The equalizer of claim 10, wherein the error measurement unit comprises a coefficient update unit to receive the step size from the step size decision unit and to update the tap coefficient of the filter unit according to the determined error value and the step size.

20. The equalizer of claim 10, wherein the error measurement unit comprises a signal to noise measurement unit to measure a signal to noise ratio according to the determined error value and the output of the filter unit.

21. A receiver, comprising:
a least mean squares (LMS) equalizer; and
a step size auto-controlling device to adjust a step size of the LMS equalizer, thereby compensating distortions of a received signal under different channel environments, comprising:
an SNR (Signal to Noise Ratio) measurement block to measure a signal to noise ratio of an output signal from the LMS equalizer, and a step size decision block to receive the signal to noise ratio from the SNR measurement block, to change a step size used to update a tap coefficient of the LMS equalizer until the signal to noise ratio exceeds a predetermined value, and to transfer the changed step size to the LMS equalizer.

22. The receiver of claim 21, wherein the receiver is a digital broadcast receiver, and the received signal comprises a digital broadcast signal in 8 VSB (Vestigial Side Band) form.

23. A receiver, comprising:
a least mean squares (LMS) equalizer to receive a signal and equalize the received signal according to a tap coefficient; and
a step size controlling apparatus to monitor a channel environment of the received signal and to set a step size used to update the tap coefficient according to the monitored channel environment.

24. The receiver of claim 23, wherein the step size controlling apparatus monitors the channel environment by periodically determining a signal to noise ratio and performing one of a large change in the step size, a small change in the step size, or no change in the step size according to the determined signal to noise ratio.

25. A method of automatically controlling a step size of a least mean square (LMS) equalizer, the method comprising:
measuring a signal to noise ratio (SNR) of an output signal of the LMS equalizer; and
changing the step size until the measured SNR exceeds a predetermined value and transferring the changed step size to the LMS equalizer.

26. The method according to claim 25, wherein the measuring of the SNR comprises measuring a cumulative error value received from the LMS equalizer, the cumulative error value being a sum of error values accumulated, in which an error value is a difference between an output of an equalizer filter of the LMS equalizer and a reference symbol signal, and the cumulative error value is inversely proportional to the SNR.

27. The method according to claim 26, wherein the measuring of the SNR comprises measuring the error value of the LMS equalizer while the LMS equalizer operates at a current step size and converges, and the cumulative error value is determined by adding the error values accumulated while the LMS equalizer operates at the current step size.

28. The method according to claim 26, wherein the measuring of the SNR comprises adding the error values of at least one field signal period of a digital broadcast data received through 8 VSB form, and the cumulative error value is calculated per field signal period.

29. The method according to claim 28, wherein the cumulative error value is a sum of errors generated when at least one of a test stream data and a segment sync symbol of a field segment is input to the LMS equalizer.

30. The method according to claim 25, further comprising:
selecting a first step size between a predetermined upper limit and a predetermined lower limit and changing the first step size at predetermined regular time intervals such that the first step size is increased or decreased sequentially by a first predetermined size;
selecting a second step size within a range defined by the first predetermined size and changing the second step size at the predetermined regular time intervals such that the second step size is increased or decreased sequentially by a second predetermined size; and
adding the first step size and the second step size to determine a final step size to be transferred to the LMS equalizer.

31. The method according to claim 30, wherein time taken by the LMS equalizer to converge periodically according to the determined final step size is equal to the predetermined regular time intervals.

32. The method according to claim 30, wherein the predetermined regular time intervals comprise at least one field signal period of a digital broadcast data received through 8 VSB form periodically.

33. The method according to claim 30, wherein:
the selecting of the first step size comprises receiving a cumulative error value derived from the SNR, and if the cumulative error value is less than a predetermined first threshold, the first step size is maintained without change; and
the selecting of the second step size comprises receiving the measured cumulative error value, and if the cumulative error value derived from the SNR is less than a predetermined second threshold that is less than the predetermined first threshold, or if the cumulative error value is greater than the predetermined first threshold, the second step size is maintained without change.

34. A method of determining a step size in a least mean squares (LMS) equalizer, the method comprising:
detecting a channel environment of a received signal; and
determining a step size to update a tap coefficient of the LMS equalizer according to the detected channel environment.

35. The method of claim 34, wherein the detecting of the channel environment comprises measuring a signal to noise ratio of the received signal.

36. The method of claim 35, wherein the determining of the step size comprises:
monitoring the channel environment of the received signal; and
changing the step size by a large amount when the signal to noise ratio is below a predetermined range, changing the step size by a small amount when the signal to noise ratio is within the predetermined range, and maintaining the step size when the signal to noise ratio is above the predetermined range.

37. The method of claim 35, wherein the detecting of the channel environment comprises periodically determining whether a new step size is needed by determining whether the channel environment has changed.

38. A method of adapting a step size of a least mean square (LMS) equalizer, the method comprising:
filtering a signal according to a tap coefficient;
determining an error value of the filtered signal and updating the tap coefficient according to a step size; and
adapting the step size by maintaining the step size, changing the step size by a first amount, or changing the step size by a second amount according to the determined error value.

39. The method of claim 38, wherein the determining of the error value of the filtered signal comprises:
determining whether the error value falls within a predetermined error range; and
changing the step size by the first amount when the error value is larger than the predetermined error range, changing the step size by the second amount when the error value falls within the predetermined error range, and maintaining the step size when the error value is less than the predetermined error range.

40. The method of claim 38, wherein the first amount is a multiple of the second amount.

41. The method of claim 38, wherein the error value comprises a cumulative error value taken over a predetermined time that the filter unit operates.

42. The method of claim 41, wherein the adapting of the step size comprises:
selecting a first step size by determining whether the cumulative error value exceeds a first threshold, and changing the first step size by the first amount when the cumulative error value exceeds the first threshold; and
selecting a second step size by determining whether the cumulative error value exceeds a second threshold that is less than the first threshold, and changing the second step size by the second amount when the cumulative error value falls between the first threshold and the second threshold; and
adding the first step size and the second step size to determine a final step size and outputting the final step size as the step size.

43. The method of claim 42, wherein the final step size is maintained until the error value of the LMS equalizer converges.

44. The method of claim 41, wherein the predetermined time is periodic and comprises an amount of time it takes the LMS equalizer to converge on a minimum mean squared error according to the step size.

45. The method of claim 41, wherein the predetermined time is periodic and depends on one of a field sync signal and a segment sync signal.

46. The method of claim 38, further comprising:
decoding an output of the filter unit by outputting a reference symbol signal.

47. The method of claim 38, wherein the determining of the error value comprises determining a signal to noise ratio according to the determined error value and an output of the LMS equalizer.
